(19) United States
(12) Patent Application Publication
(10) Pub. No.: US 2001/0012701 A1
(43) Pub. Date: Aug. 9, 2001

(54) Method of forming a silicon nitride thin film

(75) Inventors: Young Mook Kang, Songnam-shi (KR); Sang Do Lee, Pundang-gu (KR)

Correspondence Address: George C. Beck, FOLEY & LARDNER, Washington Harbour, 3000 K Street, N.W., Suite 500, Washington, DC, 20007-5109, US

(73) Assignee: Jusung Engineering Co., Ltd

(21) Appl. No.: 09/767,682

(22) Filed: Jan. 24, 2001

(30) Foreign Application Priority Data
Jan. 25, 2000 (KR) 2000-3432

(51) Int. Cl. H01L 21/31; H01L 21/469

(52) U.S. Cl. 438/791

(57) ABSTRACT

A method of forming a silicon nitride thin film by using a PECVD process, in which a silicon nitride thin film is formed according to the PECVD process a temperature range of about 550 to 700° C. by using plasma maintained by a high frequency power in the range of about 200 to 1000 W. Plasma can be generated by using a mixed gas of SiH₄, NH₃ and N₂. According to the invention, a hot temperature process is associated with the PECVD process so that the silicon nitride thin film of the invention can be free from problems of the silicon nitride thin films formed by the PECVD process and the LPCVD process.

### BACKGROUND OF THE INVENTION

1. Field of the Invention

The invention relates to a method of forming a silicon nitride thin film, and in particular a method of forming a silicon nitride thin film by the use of a PECVD(Plasma Enhanced Chemical Vapor Deposition) process.

2. Description of the Prior Art

In fabricating a semiconductor device, a silicon nitride thin film is widely applied to an IMD(Inter Metal Dielectric) film, etch stop layer or passivation film. These silicon nitride thin films are generally formed by the use of a LPCVD process(Low Pressure Chemical Vapor Deposition) process or a PECVD process.

The LPCVD process generally uses the following equation 1 at a temperature of at least 750° C.:

3SiCl₂H₂+4NH₃→Si₃N₄+6HCl+6H₂ equation 1.

The silicon nitride thin film formed by the LPCVD process is excellent in step coverage, hydrogen contents and density, so the LPCVD process has been widely applied in a critical process.

However, the LPCVD process has some problems in forming the silicon nitride thin film as follows:

First, the process is performed in a high temperature so that a relatively high thermal stress is given to the silicon nitride thin film thereby causing a crack generation in a relatively thick silicon nitride thin film. So, the LPCVD process has been restricted in forming a relatively thin silicon nitride thin film. In addition, as recently the semiconductor device is highly integrated, the cracks take place also in the relatively thin silicon nitride thin film. Also, since the process is proceeded in the high temperature, the features of the semiconductor device tend to deteriorate due to lack of thermal budget.

Second, most of the furnaces used in the high temperature process are batch type so that each process takes a long time for stabilization in the high temperature.

Third, the deposition rate is slow in the LPCVD process so that it is not preferable in the aspect of the productivity.

Fourth, generally according to the features of an apparatus used for the LPCVD process, the silicon nitride thin film is deposited on both sides of the substrate, a thin film is unnecessarily formed on the back side of the substrate. Therefore, the back film is unstably etched in a subsequent wet etching thereby probably causing fatal bad effects to the electric properties of the semiconductor device. Also, a misfocussing takes place in a photolithography process to deteriorate the electric characteristics of the semiconductor device.

Meanwhile, in the PECVD process, the deposition rate is speedy since reaction gases are activated by plasma, and the silicon nitride thin film can be deposited even in the relatively low temperature range of 250 to 400° C. Since the deposition rate is speedy, the PECVD process is advantageous in the productivity and can be widely applied to a non-critical process such as forming the IMD thin film and the passivation film.

However, there are also several problems in forming the silicon nitride thin film in the PECVD process as follows:

First, a large amount of hydrogen is contained in the silicon nitride thin film since a number of hydrogen atoms are not completely dissociated and reside as radical in the plasma in the relatively low temperature process. Therefore, the electric features of the semiconductor device may be deteriorated due to a threshold voltage variation of a transistor for example.

Second, the thin film is not dense.

And third, the step coverage is very poor so that there are some restrictions to apply the PECVD process to a highly integrated semiconductor device.

### SUMMARY OF THE INVENTION

It is therefore an object of the invention to provide a method of forming a silicon nitride thin film by which problems of a silicon nitride thin film formed by a PECVD process or a LPCVD process by associating the PECVD process with a high temperature process According to an example of the invention to obtain the foregoing object, it is provided a method by which a silicon nitride thin film is formed according to the PECVD process a temperature range of about 550 to 700° C. by using plasma maintained by a high frequency power in the range of about 200 to 1000 W.

Here, the PECVD process is preferably proceeded in a warm wall type chamber. The plasma can be formed by using a mixture gas of SiH₄, NH₃ and N₂. If SiH₄ gas resides as radicals of SiH₂* or SiH₃*, and NH₃ gas as radicals of NH* or NH₂* in the plasma due to incomplete dissociation of hydrogen atoms, hydrogen is contained as SiH*, SiH₂*, SiH₃*, NH* or NH₂* in the deposited silicon nitride thin film, thereby deteriorating the electric properties of a semiconductor device.

Therefore, to prevent these problems, the deposition temperature range is set as about 550 to 700° C. which is higher compared to the typical PECVD process so that hydrogen atoms can be completely dissociated in gaseous state, and the high frequency power is applied about 200 to 1000 W to maintain the plasma. Since the deposition temperature is higher than the conventional PECVD process, the thin film of the invention has more excellent density than in the conventional PECVD process.

The mixture gas is preferably introduced in the reaction chamber by at least one injector rather than a showerhead.

### BRIEF DESCRIPTION OF THE DRAWINGS

The objects and other advantages of this invention are best understood with reference to the preferred embodiment when read in conjunction with the following drawings, wherein:

FIG. 1A and FIG. 1B are sectional views for illustrating the step coverage of a silicon nitride thin film;

FIG. 2A and FIG. 2B are graphs for illustrating the etch rate of silicon nitride thin films; and

FIG. 3A and FIG. 3B are sectional views for illustrating the density of a silicon nitride thin film formed on the sidewall of a trench.

### DESCRIPTION OF THE PREFERRED EMBODIMENT

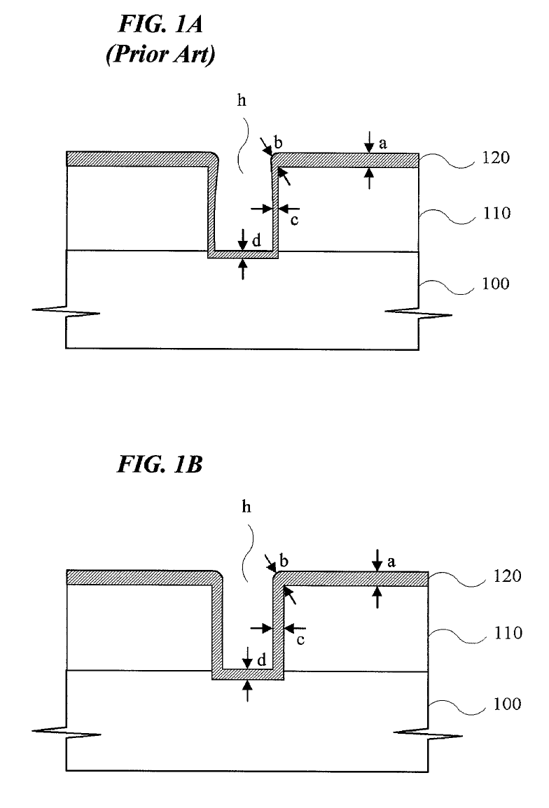

FIG. 1A and FIG. 1B are sectional views for illustrating the step coverage of a silicon nitride thin film, in which FIG. 1A shows the step coverage by a PCEVD of the prior art and FIG. 1B shows the step coverage by a PECVD process of the invention.

Referring to FIG. 1A and FIG. 1B, an insulator film 110 on a substrate 100 has a contact hole h, on which a silicon nitride thin film 120 is deposited.

Table 1 compares the result measured from FIG. 1A and FIG. 1B. Referring to Table 1, Example 1 of the invention shows more excellent step coverage than Relative Example of the conventional PECVD process.

TABLE 1

| classification | Relative Example | Example 1 |
|---|---|---|
| contact hole size | 0.503 μm | 0.511 μm |
| aspect ratio | 1.0 | 1.05 |
| step coverage | 57.6% | 76.1% |
| d/a | 50.0% | 70.0% |

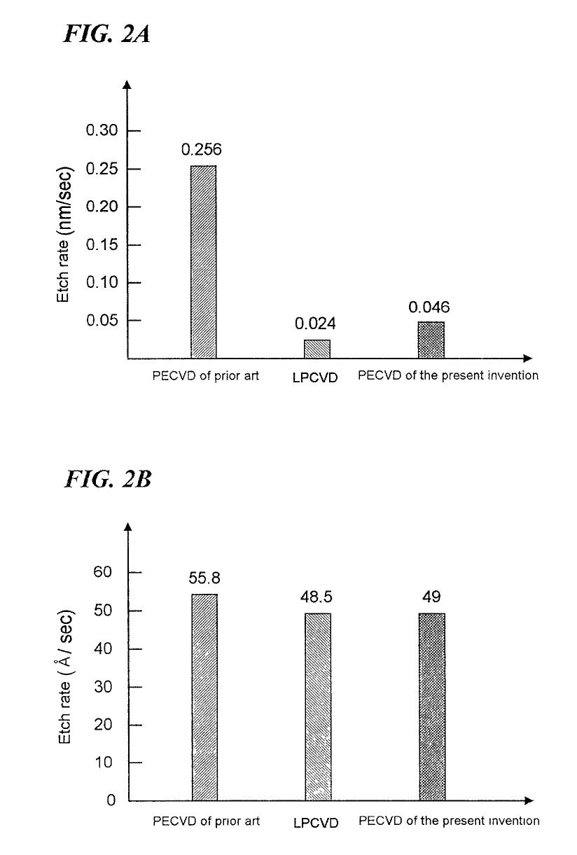

FIG. 2A and FIG. 2B are graphs for illustrating the etch rates of silicon nitride thin films, FIG. 2A shows etch rates of wet etched silicon nitride thin films by using 50:1 fluoride acid, and FIG. 2B shows etch rates of dry etched silicon nitride thin films.

Referring to FIG. 2A and FIG. 2B, the silicon nitride thin film of the invention has the etch rate smaller than that of the conventional PECVD process since the film quality of the invention is denser than that of the conventional one. Therefore, the silicon nitride thin film formed according to the invention also sufficiently serves as an etch stop layer.

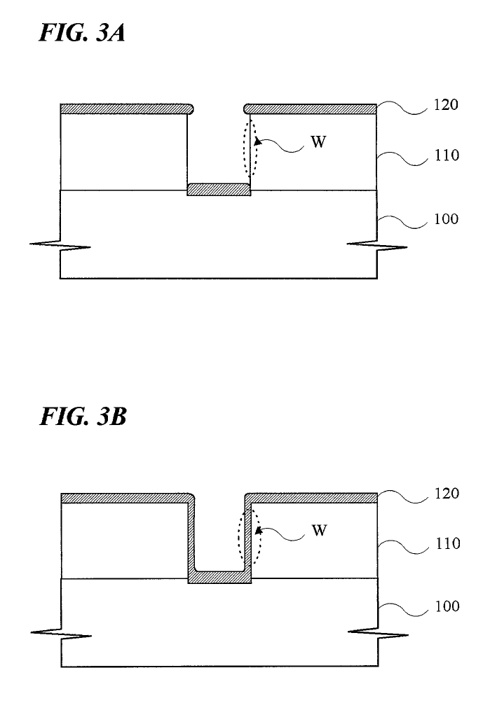

FIG. 3A and FIG. 3B are sectional views for illustrating the density of a silicon nitride thin film formed on the side wall of a trench, in which FIG. 3A shows the density according to the PECVD process of the prior art and FIG. 3B shows the density according to the PECVD process of the invention.

Referring to FIG. 3A and FIG. 3B, while the silicon nitride thin film is removed from the side wall W by the etching in the PECVD process of the prior art, the silicon nitride thin film on the side wall still exists as before without being removed by the etching in the PECVD process of the invention since the thin film density is high.

As described hereinbefore according to the method of forming the silicon nitride thin film of the invention, the high temperature process is combined with the PECVD process to form the silicon nitride thin film in which the problems of the silicon nitride thin film formed by the PECVD process or LPCVD process are solved.

While the invention has been described in detail with reference to specific embodiments thereof, it will be apparent to those skilled in the art that various changes and modifications can be made and equivalents employed without departing from the spirit and scope of the invention.

What is claimed is:

1. A method of forming a silicon nitride thin film according to the PECVD process in the temperature range of 550 to 700° C. by using plasma maintained by a high frequency power of 200 to 1000 W.

2. A method of forming a silicon nitride thin film according to claim 1, wherein the PECVD process is performed in a warm wall type reaction chamber.

3. A method of forming a silicon nitride thin film according to claim 2, wherein the plasma is formed from a mixed gas containing SiH₄ and NH₃.

4. A method of forming a silicon nitride thin film according to claim 3, wherein the mixed gas is introduced into the reaction chamber by at least one injector.
